(19) United States
(12) Patent Application Publication
(10) Pub. No.: US 2014/0193762 A1
(43) Pub. Date: Jul. 10, 2014

(54) HEAT TREATMENT FURNACE

(71) Applicants: Mario Grenier, Marie Victorian Saint-Nicolas (CA); Nicolas Lévesque, de Poitiers (CA); Serge Adam, boul.Allard St-Nicephore (CA); Christian Côté, Rue Des Lilas St-Redempteur (CA); Alex Grenier-Desbiens, app. 1 St-Nicolas (CA); James Demarest, South Canton, MI (US)

(72) Inventors: Mario Grenier, Marie Victorian Saint-Nicolas (CA); Nicolas Lévesque, de Poitiers (CA); Serge Adam, boul.Allard St-Nicephore (CA); Christian Côté, Rue Des Lilas St-Redempteur (CA); Alex Grenier-Desbiens, app. 1 St-Nicolas (CA); James Demarest, South Canton, MI (US)

(73) Assignee: PYROMAITRE INC., St-Nicolas, QC (CA)

(21) Appl. No.: 13/700,160

(22) PCT Filed: May 27, 2011
(86) PCT No.: PCT/CA11/00634

§ 371 Date: May 13, 2013

(30) Foreign Application Priority Data
May 27, 2010 (CA) 2705650

(51) Int. Cl. H01L 31/18; F27D 19/00; F27B 3/24; F27D 7/06; F27B 3/04; F27B 3/20

(52) U.S. Cl. CPC H01L 31/18; F27B 3/04; F27B 3/20; F27B 3/24; F27D 7/06; F27D 19/00
USPC 432/56; 432/57; 432/207; 432/77; 432/128

(57) ABSTRACT

A heat treatment furnace, also referred to as a multi-chamber furnace, that includes a plurality of treatment chambers, each having heating and cooling dampers and being controllable to adjust a flow rate into the treatment chamber, the dampers of each treatment chamber being selectively and independently adjustable with respect to one another so as to allow simultaneous heat processing of a plurality of products in different treatment chambers at different respective heat treatment states depending on the amount of heating and cooling flow rates allowed to enter in each treatment chamber via the dampers.

### FIELD OF THE INVENTION

The present invention relates to a furnace. More particularly, the present invention relates to a heat treatment furnace having several juxtaposed treatment chambers, and also relates to a corresponding tray to be used with said heat treatment furnace and adapted to carry a vacuum unit.

### BACKGROUND OF THE INVENTION

It is known in the art that solar cell panels include an outer rigid transparent layer of glass or plastic material to which are applied plastic layers, such as polyvinyl butyral between which are positioned a plurality of solar cell wafers. Generally, a thin flexible film of polyethylene terephthalate forms the other outer surface of the panel. Typically, the panel is manufactured by laminating the materials together with the margins of the plastic film extending beyond the polyvinyl butyral layers so that the film can be brought into direct contact and sealed to a rigid base plate, forming a fully encapsulating structure. The assembled structure is then evacuated to withdraw air and to squeeze the layers together to promote adhesion. The evacuated laminate structure is then placed in a furnace for applying heat and pressure to the laminated structure for permanent bonding.

The heating process is carried out in a furnace and vacuum should be maintain continuously between the assembling step and the curing step, which occurs in the furnace, and during the curing step.

Furthermore, it is well known that continuous processes are usually advantageous over batch processes. However, conventional processes used for manufacturing solar cell panels are not adapted to be operated into an entirely continuous process. Therefore, there is a need to provide a new system which would be able to increase the productivity of a heating furnace in order to reduce the downtime, in order to improve overall efficiency, and/or in order to provide better end results.

Hence, in light of the above-discussed, there is a need for an improved heat treatment furnace, which by virtue of its design and components, would be able to overcome or at the very least minimize some of the above-mentioned prior art problems and drawbacks.

### SUMMARY OF THE INVENTION

An object of the present invention is to provide a heat treatment furnace (hereinafter referred to also as a “multi-chamber furnace”, or also simply as a “furnace”) which satisfies some of the above-mentioned needs, and which is thus an improvement over other related heat treatment furnaces and/or corresponding heat treatment methods known in the prior art.

In accordance with the present invention, the above object is achieved, as will be easily understood, with a heat treatment furnace such as the one briefly described herein and such as the one exemplified in the accompanying drawings.

More particularly, according to one aspect of the present invention, there is provided a heat treatment furnace for simultaneously heat processing a plurality of products at different respective heat treatment states, the heat treatment furnace comprising:

a plurality of treatment chambers each configurable for heat processing a given product, and each being provided with a corresponding product door selectively operable between open and closed configurations for respectively allowing the introduction and removal of the given product to be processed inside the treatment chamber;

at least one first damper and at least one second damper associated with each corresponding treatment chamber, each damper being selectively operable between at least one open configuration where at least one processing fluid of the furnace is allowed to enter the corresponding treatment chamber and at least one closed configuration where said at least one processing fluid is prevented from entering the corresponding treatment chamber;

a first source of processing fluid being fluidly connected to each treatment chamber via a corresponding damper thereof for providing said treatment chamber with a first processing fluid; and

a second source of processing fluid being fluidly connected to each treatment chamber via a corresponding damper thereof for providing said treatment chamber with a second processing fluid;

the dampers of each treatment chamber being selectively and independently adjustable with respect to one another so as to allow simultaneous heat processing of a plurality of products in different treatment chambers at different respective heat treatment states depending on the amount of first and second processing fluids allowed to enter in each treatment chamber via the dampers thereof.

According to another aspect of the present invention, there is also provided a multi-chamber furnace comprising:

a plurality of treatment chambers isolated from one another and each having at least two heating dampers and at least two cooling dampers, the heating and cooling dampers being configurable in a closed configuration and a plurality of open configurations and being controllable to adjust a gas flowrate in the respective treatment chamber, and at least one product door allowing product introduction in and product removal from the respective treatment chamber;

at least one heat generating unit and at least one heating blower in gas communication with the heating dampers of the chambers with gas communication being allowed with the chambers in the open configurations of the heating dampers and gas communication being prevented in the closed configuration of the heating dampers; and

at least one cooling blower in gas communication with the cooling dampers of the chambers with gas communication being allowed with the chambers in the open configurations of the cooling dampers and gas communication being prevented in the closed configuration of the cooling dampers.

According to yet another aspect of the present invention, there is also provided a tray for a heat treatment furnace comprising:

a furnace section having a base for supporting at least one product to be heat treated and insertable in the heat treatment furnace; and

a vacuum unit section having a vacuum unit mounted thereto, remaining outside the heat treatment furnace when the furnace section is inserted therein, and having a gas conduit operatively connected to the vacuum unit and extending to the furnace section for maintaining vacuum in association with the at least one product supported by the furnace section.

Among other objectives, the present invention seeks to increase productivity and reduces downtime between lots of processed products in a batch process, when compared to what is possible with conventional systems known in the art.

An important advantage resulting from the present invention resides in that energy consumption for heat treatment is reduced as the entire furnace is capable of being operated in a manner that it need never be entirely cooled down for the cooling cycle or for preparation of the next load. Thus, the continuous output of the multi-chamber heat treatment furnace is more efficient in that less in-process material and/or inventory is required when compared to conventional systems.

The present invention is also advantageous in that due to its structural and functional components/features, an improved level of quality control is achieved as defective parts of the multi-chamber heat treatment furnace can be identified sooner, and be inspected, maintained, repaired and/or replaced more easily and efficiently.

According to another aspect of the present invention, there is also provided a processing plant provided with the above-mentioned heat treatment furnace.

According to another aspect of the present invention, there is provided a method of operating the above-mentioned heat treatment furnace and/or tray.

According to another aspect of the present invention, there is also provided a kit with corresponding components for assembling the above-mentioned heat treatment furnace and/or tray.

According to another aspect of the present invention, there is also provided a set of components for interchanging with certain components of the above-mentioned kit.

According to another aspect of the present invention, there is also provided a method of assembling components of the above-mentioned kit and/or set.

According to another aspect of the present invention, there is also provided a method of manufacturing one or several of the above-mentioned components.

According to another aspect to the present invention, there is also provided a product having been processed with the above-mentioned heat treatment furnace, tray and/or method(s).

The objects and advantages of the present invention will become more apparent upon reading of the following non-restrictive description of preferred embodiments thereof, given for the purpose of exemplification only, with reference to the accompanying drawings.

### BRIEF DESCRIPTION OF THE DRAWINGS

FIG. 1 is a front elevational view of a multi-chamber furnace according to a preferred embodiment of the present invention.

FIG. 2 is a rear elevational view of what is shown in FIG. 1.

FIG. 3 is a longitudinal cross-sectional view of the multi-chamber furnace shown in FIG. 1.

FIG. 4 is a cross-sectional view along section line IV-IV of FIG. 3, said cross-sectional view illustrating a tray fully inserted in a treatment chamber according to a preferred embodiment of the present invention.

FIG. 5 is a cross-sectional view along section line V-V of FIG. 3, said cross-sectional view illustrating a heat transfer unit according to a preferred embodiment of the present invention.

FIG. 6 is a cross-sectional view along section line VI-VI of FIG. 3, said cross-sectional view illustrating cooling dampers according to a preferred embodiment of the present invention.

FIG. 7 is a cross-sectional view along section line VII-VII of FIG. 3, said cross-sectional view illustrating a combustion chamber according to a preferred embodiment of the present invention.

FIG. 8 is a cross-sectional view along section line XIII-XIII of FIG. 3, said cross-sectional view illustrating several trays inserted in their respective treatment chambers according to a preferred embodiment of the present invention.

FIG. 9 is a cross-sectional view along section line IX-IX of FIG. 3, said cross-sectional view illustrating connections between the trays inserted in their respective treatment chambers and their respective vacuum units according to a preferred embodiment of the present invention.

FIG. 10 is a perspective view of a tray provided with a vacuum unit and configured to be used with a multi-chamber furnace according to a preferred embodiment of the present invention.

FIG. 11 is a top plan view of what is shown in FIG. 10.

FIG. 12 is a side elevational view of what is shown in FIG. 11.

FIG. 13 is a bottom plan view of what is shown in FIG. 12.

FIG. 14 is an enlarged perspective view of the vacuum unit shown in FIG. 10.

While the invention will be described in conjunction with preferred embodiments given as way of mere examples, it is be understood that they are not intended to limit the scope of the present invention to such embodiments. On the contrary, it is intended to cover all possible alternatives, modifications and/or technical equivalents, with which the present invention could be used and may be useful, as apparent to a person skilled in the art.

### DETAILED DESCRIPTION OF PREFERRED EMBODIMENTS OF THE INVENTION

In the following description, the same numerical references refer to similar elements. The embodiments, geometrical configurations, materials mentioned and/or dimensions shown in the figures or described in the present description are preferred embodiments only, given for exemplification purposes only.

Moreover, although the present invention was primarily designed for use in the field of thermal processing of products, such as heat furnaces used for manufacturing solar cell panels and the like, for example, using namely sources of “heating” and “cooling”, the invention may be used with various other types of objects, and in various other fields, where products are to be processed, using an appropriate and adjustable mixture of two generally opposite parameters (“heat” versus “cold”, “spaying” versus “drying”, etc.), as can be easily understood by a person skilled in the art. Hence, expressions such as “thermal”, “processing”, “heating”, “cooling”, “manufacturing”, “solar”, “cell”, “panel”, etc., as used in the present description, and/or any other reference and/or equivalent or similar expression to the latter should not be considered as limiting the scope of the present invention and include any other objects, substitutes, and/or any other applications with which the present invention may be used and may be useful, as can be easily understood by a person skilled in the art.

Moreover, in the context of the present description, expressions such as “furnace”, “oven”, “device”, “system”, “mechanism”, “product”, “assembly”, etc. as well as any other equivalent expressions and/or compounds word thereof known in the art will be used interchangeably, as apparent to a person skilled in the art. This applies also for any other mutually equivalent expressions, such as, for example: a) “manufacturing”, “assembling”, “processing”, “treating”, “heating”, “drying”, “baking”, “roasting”, “curing”, “crystallizing”, “solidifying”, “smoking”, etc.; b) “cooling”, “blowing”, “spraying”, “ventilating”, etc.; c) “passage”, “slot”, “orifice”, “groove”, “conduit”, “port”, “channel”, entry”, etc.; d) “material”, “substance”, “product”, “panel”, “load”, “batch”, etc.; e) “allow”, “force”, “draw”, “urge”, “blow”, etc.; f) “converging”, “funnelling”, “narrowing”, etc.; g) “gas”, “fluid”, “air”, “spray”, etc.; h) “juxtaposed”, “superposed”, “superimposed”, “adjacent”, “neighbouring”, etc.; i) “rollers”, “gliders”, “sliders”, “supports”, etc.; j) “dampers”, “doors”, actuators”, “ports”, etc.; as well as for any other mutually equivalent expressions, pertaining to the aforementioned expressions and/or to any other structural and/or functional aspects of the present invention, as also apparent to a person skilled in the art.

Furthermore, in the context of the present description, it will be considered that all elongated objects will have an implicit longitudinal axis, and that expressions such as “connected” and “connectable”, or “mounted” and “mountable”, may be interchangeable, in that the present invention also relates to a kit with corresponding components for assembling a resulting fully assembled heat treatment furnace, and/or a corresponding tray provided with a vacuum unit to be used with said heat treatment furnace. Furthermore, it can be easily understood that the treatment chambers or other components of the heat treatment furnace are not necessarily limited to “rectangular” configurations, and may take on various other suitable shapes and/or configurations depending on the particular applications for which the heat treatment surface is intended for, and the desired end result, as apparent to a person skilled in the art.

In addition, although the preferred embodiments of the present invention as illustrated in the accompanying drawings comprise various components, and although the preferred embodiments of the heat treatment furnace and corresponding components of the present invention as shown consists of certain geometrical configurations as explained and illustrated herein, not all of these components and geometries are essential to the invention and thus should not be taken in their restrictive sense, i.e. should not be taken so as to limit the scope of the present invention. It is to be understood, as also apparent to a person skilled in the art, that other suitable components and cooperations thereinbetween, as well as other suitable geometrical configurations, may be used for the present heat treatment furnace and corresponding components thereof according to the present invention, as briefly explained herein and as can be easily inferred herefrom, without departing from the scope of the invention.

### LIST OF NUMERICAL REFERENCES OF SOME OF THE CORRESPONDING PREFERRED COMPONENTS ILLUSTRATED IN THE ACCOMPANYING DRAWINGS

20. heat treat furnace (or “multi-chamber furnace”)

22. treatment chamber

24. insulated partition

26. longitudinal wall

28. lateral wall

30. product door

32. inner housing (of furnace)

34. outer housing (of furnace)

36. combustion chamber

38. cooling chamber

40. main section (of combustion chamber)

42. longitudinal section (of combustion chamber)

44. lateral section (of cooling chamber)

46. central duct

48. heat generating unit

50. blower

52. cooling blower

54. cooling unit (or “heat exchanger”)

56. heating damper

58. cooling damper

60. outer housing door

70. tray

71. tray frame

72. extension section (of tray)

73. roller

74. vacuum unit section (of tray)

76. furnace section (of tray)

78. vacuum unit

80. housing

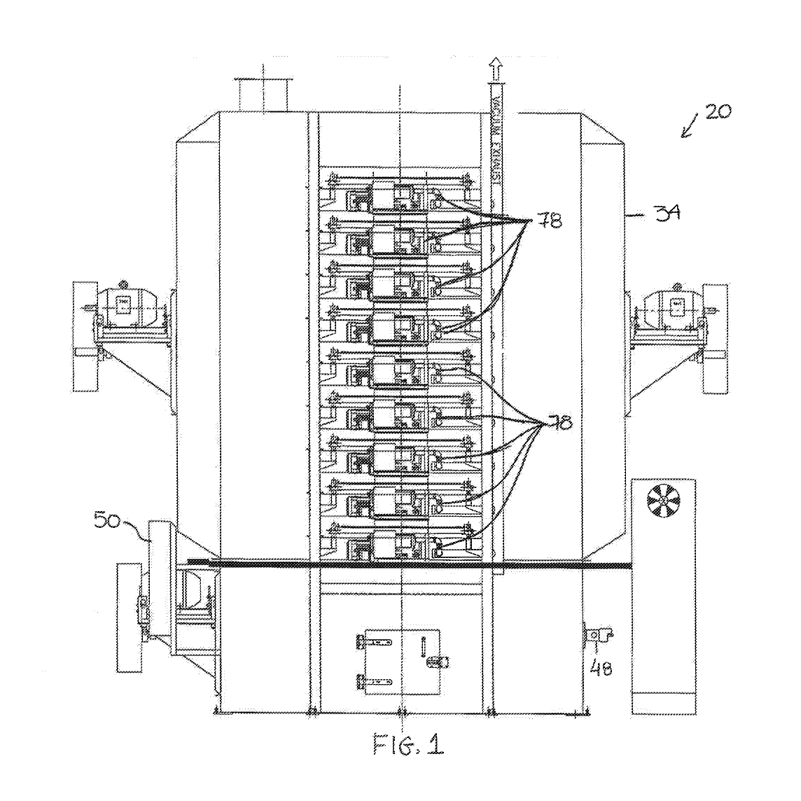

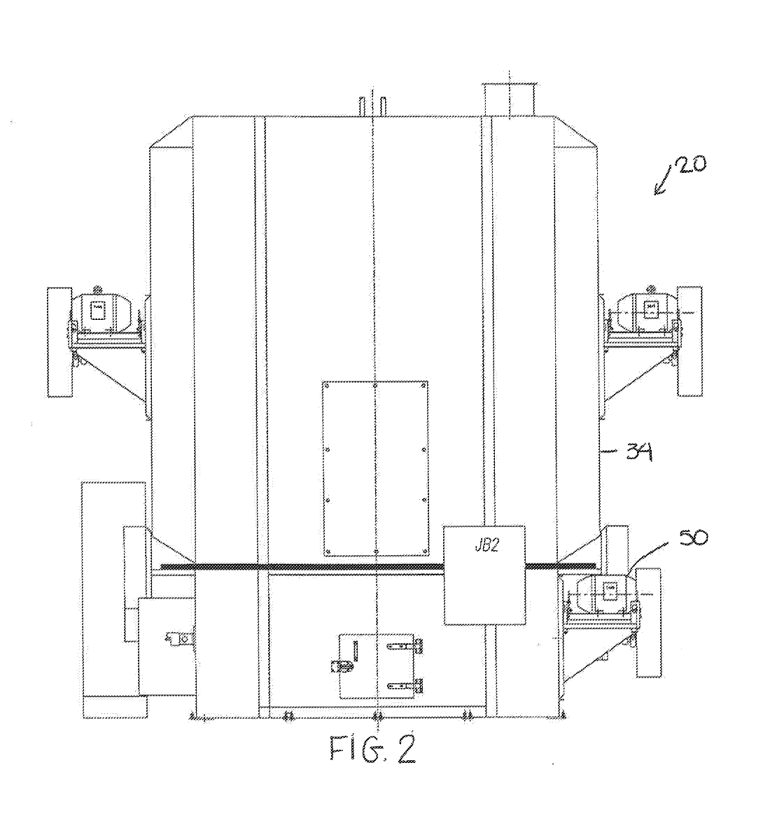

Broadly described, the present invention, as exemplified in the accompanying drawings, and more particularly in FIGS. 1-3, relates to a multi-chamber furnace (20) or “oven”. The furnace (20) has several vertically superposed treatment chambers (22). Insulated partitions (24) separate the treatment chambers (22) from one another. The insulated partitions (24) define the chamber floors and ceilings of the treatment chambers (22). More particularly, an insulated partition (24) provides a ceiling for a first treatment chamber (22) as well as a floor for a second or an “adjacent” treatment chamber (22), superposed to the first treatment chamber (22). Each treatment chamber (22) also preferably has two longitudinal spaced-apart walls (26) and two lateral spaced-apart walls (28). The content of each treatment chamber (22) is preferably isolated from the other treatment chambers (22), i.e. the content (ex. heat, gas, fluid, product, etc.) cannot flow from one treatment chamber (22) to the other during a given treatment process (ex. heat treatment process, etc.). As better shown in FIG. 6, a product door (30) is provided in one of the walls of each one of the chambers (22), such as a lateral wall (28) for example, through which product(s) to be treated can be introduced into and removed from the treatment chambers (22). In other words, each treatment chamber (22) is preferably designed to operate in a batch process, as it will be described in greater detail below.

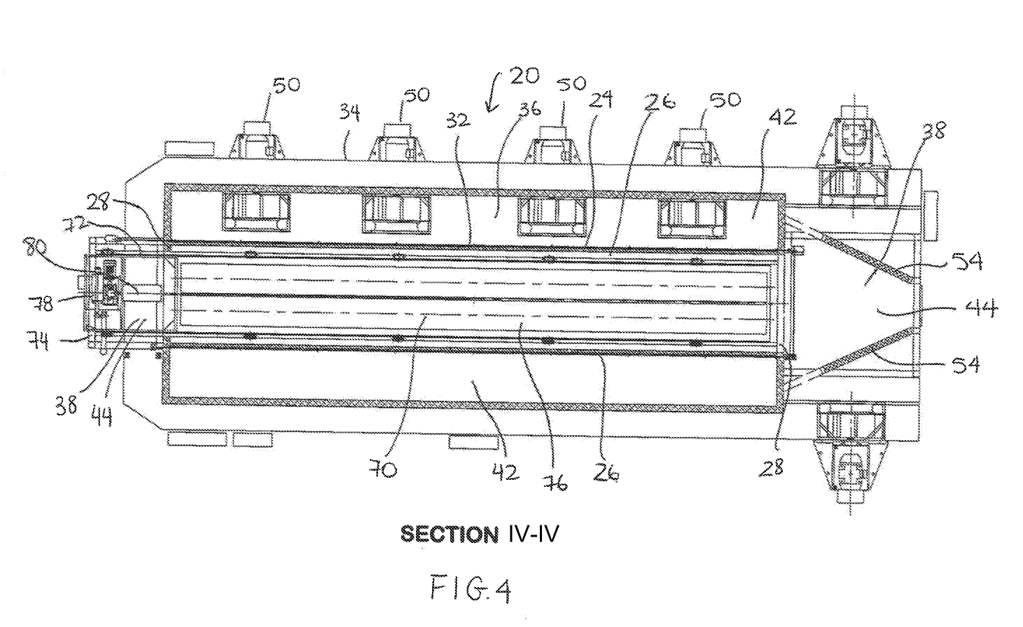

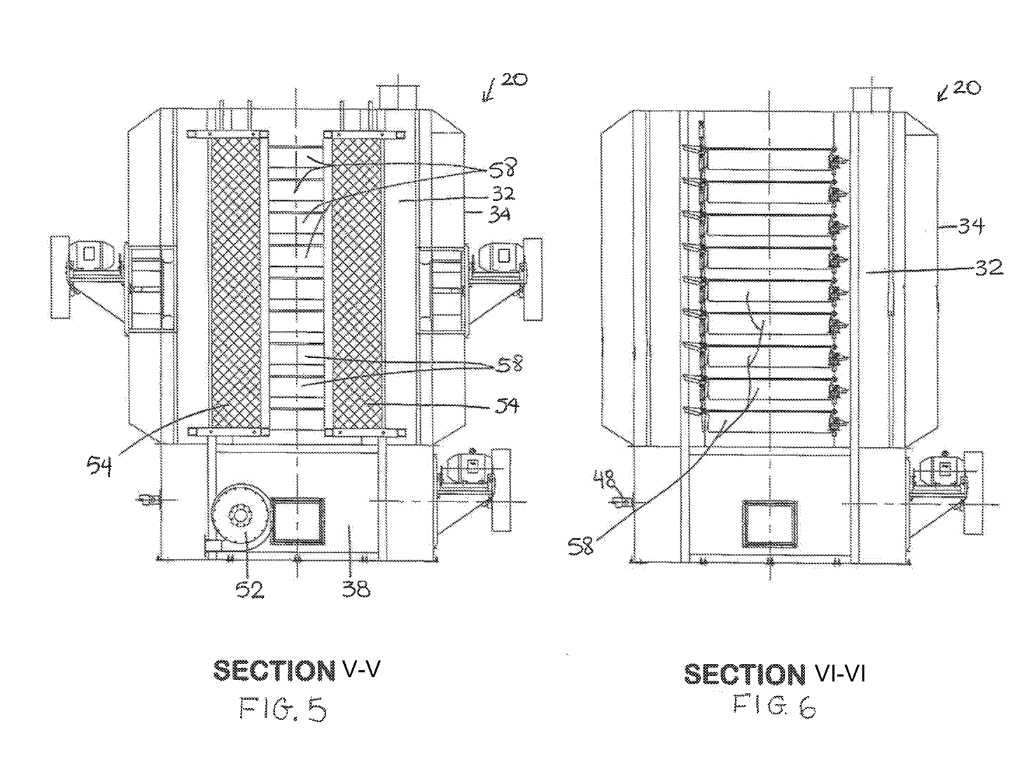

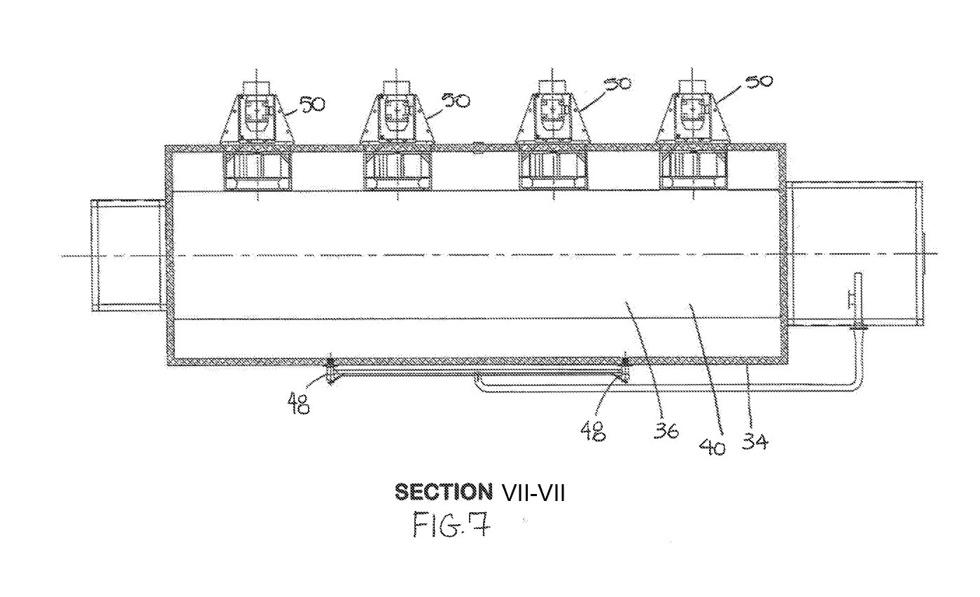

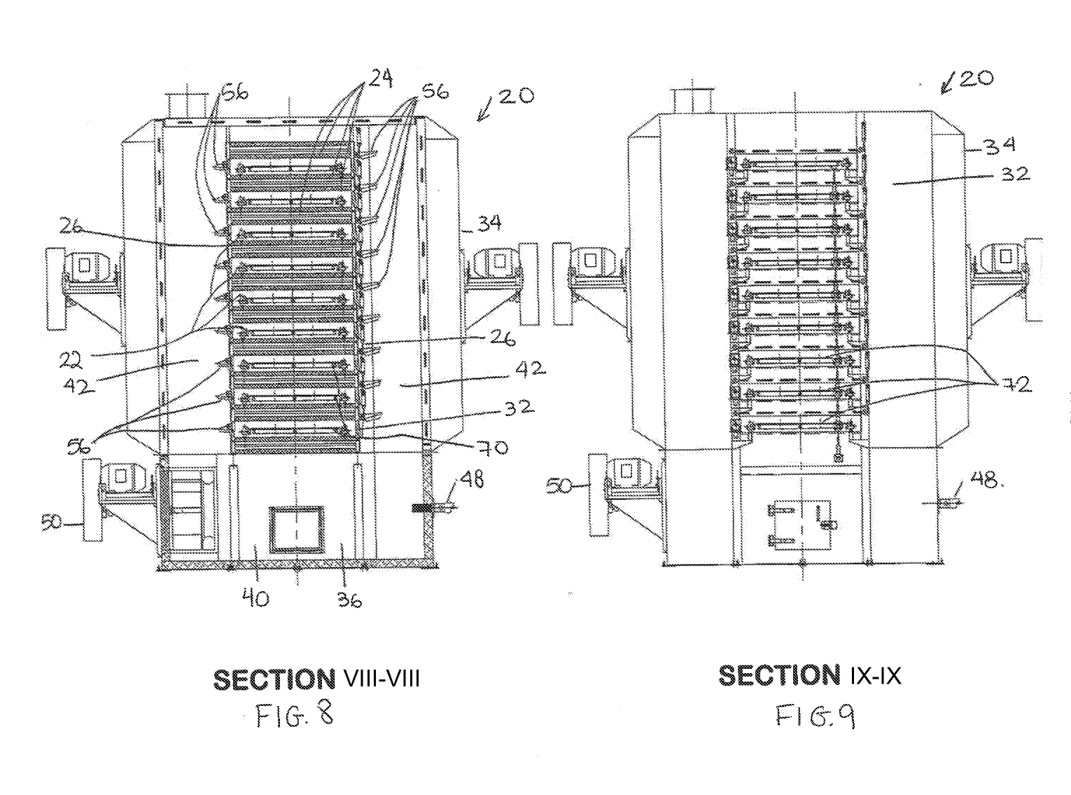

As shown in FIG. 4, the vertically superposed treatment chambers (22) define an inner housing (32) of the furnace (20). The furnace (20) also includes an outer housing (34) which comprises a plurality of inner chambers (22), the outer housing (34) enclosing the inner housing (32).

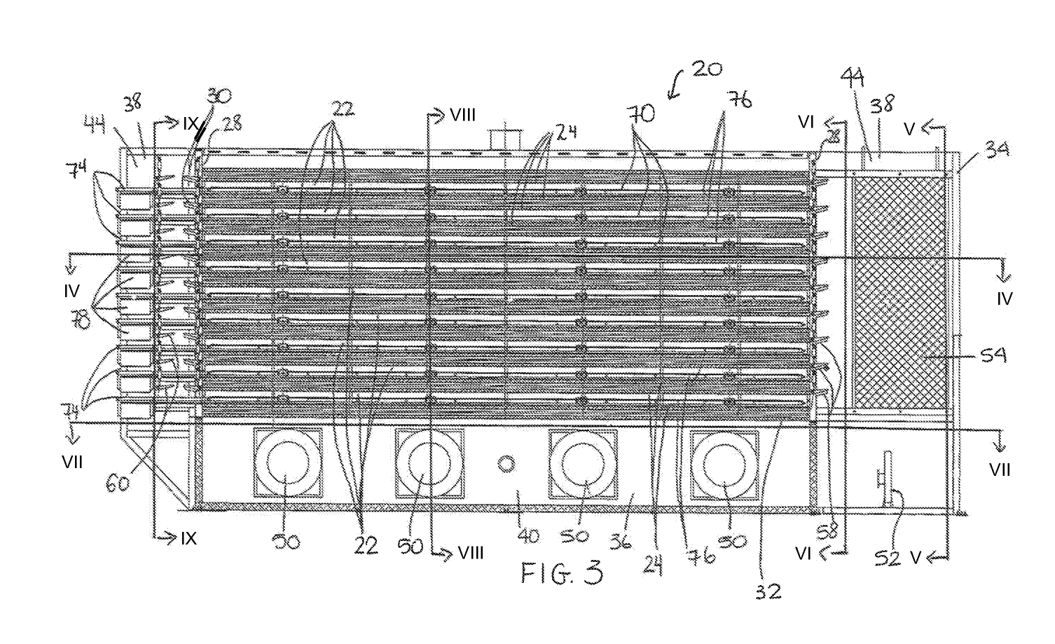

The outer housing (34) also includes a combustion chamber (36) (or heat generating chamber) and a cooling chamber (38). In the embodiment shown, the combustion chamber (36) includes a main section (40) located below the inner housing (32) as shown in FIGS. 7 and 8 and two longitudinal sections (42), spaced apart from one another, each being located on a respective side of the inner housing (32), extending upwardly from the main section (40) towards an upper treatment chamber (22) and in gas communication with the main section (40), as shown in FIGS. 4 and 8. The cooling chamber (38) of the outer section (34) preferably includes two lateral sections (44) spaced apart from one another, each being located on a respective side of the inner housing (32) and in gas communication through a central duct (46) extending above the upper treatment chamber (22), as better shown in FIG. 3. As will be described in greater detail hereinbelow, the combustion chamber (36) and the cooling chamber (38) are designed to be in gas communication (ex. “fluidly” connected) with the treatment chambers (22).

Referring now to FIGS. 4 and 8, there is shown that a heat generating unit (48) and blowers (50) are located in or communicate with the main section (40) of the combustion chamber (36). The heat generating unit (48), such as burners, for example, generates heat to warm gases circulating in the combustion and the treatment chambers (36,22). The blowers (50), such as fans or other gas propellers, for example, are used to propel gases, heated by the heat generating unit (48), within the combustion chamber (36) and the treatment chambers (22). The heat generating unit (48) and the blowers (50) are located below the treatment chambers (22).

FIGS. 3 and 5 shows that the cooling chamber (38) includes a blower (52), a fan or other gas propeller(s), for example, for propelling cooling gases or air within the cooling chamber (38) and the treatment chambers (22). In the embodiment shown, the cooling blower (52) is located in a lower portion of the cooling chamber (38), on the side opposite to the product doors (30). It can also include a heat exchanger or a cooling unit (54) for cooling the cooling gases before being introduced into one or a plurality of treatment chambers (22). In the embodiment shown, the heat exchanger (54) is located on the lateral side opposed to the product doors (30), above the cooling blower (52).

The heating and cooling gases circulating in the combustion chamber (36) and the cooling chamber (38) are in gas communication with the treatment chambers (22) through openings defined in the longitudinal and lateral walls (26,28) of the inner housing (32) respectively. Heating and cooling dampers (56,58) are mounted to the longitudinal and lateral walls (26,28) and are configurable to cover or partially cover the openings to adjustably vary the heating and cooling gas flowrate circulating in the treatment chambers (22).

More particularly, each treatment chamber preferably has two sets of heating dampers (56), as better shown in FIG. 6, each being mounted respectively to a respective one of the two longitudinal walls (26), and two sets of cooling dampers (58), as better shown in FIG. 3, each being mounted respectively to a respective one of the two lateral walls (28). Each set of heating and cooling dampers (56,58) includes at least one damper (i.e. “shutter”, “actuator”, “controller”, “gate”, etc.). Thus, heating gases can flow into one of the treatment chambers (22) through a first set of heating dampers (56) positioned on a first longitudinal wall (26) and out of the treatment chamber (22) through a second set of heating dampers (56) positioned on a second longitudinal wall (26), opposed to and spaced-apart from the first longitudinal wall (26). Similarly, cooling gases can flow into one of the treatment chambers (22) through a first set of cooling dampers (58) positioned on a first lateral wall (28) and out of the treatment chambers (22) through a second set of cooling dampers (58) positioned on a second lateral wall (28), preferably opposite to and spaced-apart from the first lateral wall (28).

In the embodiment shown, the cooling gases enter in the treatment chambers (22) through the openings defined in the lateral wall (26) opposed to the product doors (30) and flow outwardly through the openings defined in the lateral wall (26) including the product doors (30), in an open configuration of the cooling dampers (58). The cooling and heating gases are preferably re-circulated within the furnace (20).

The heating and the cooling dampers (56,58) are configurable in a closed configuration wherein gas communication with the treatment chambers (22) is prevented and a plurality of open configurations wherein gas communication with the treatment chambers (22) is allowed. The damper opening is selectively adjustable to vary the air flowrate in each treatment chamber (22), independently of the other treatment chambers (22).

As mentioned above, the heating dampers (56) are configurable in one of a plurality of open configurations to allow the heating gases to flow in and out of the chambers (22). Since each treatment chamber has its own set of heating dampers, the heating gas flowrate circulating in each treatment chamber (22) is independently controllable. To control the temperature in the chambers (22) during a heating cycle, the opening of the heating dampers (56) is selectively adjusted, i.e. the damper openings are the actuated variables or parameters to control the temperature within each of the treatment chambers (22).

Similarly and as mentioned above, the cooling dampers (58) are configurable in one of a plurality of open configurations to allow the cooling gases to flow in and out of the chambers (22). Since each treatment chamber (22) has its own set of cooling dampers (58), the cooling gas flowrate circulating in each treatment chamber (22) is independently controllable. To control the temperature in the chambers (22) during a cooling cycle, the opening of the cooling dampers (58) is selectively adjusted, i.e. the damper openings are the actuated variables or parameters to control the temperature within each the treatment chambers (22).

It is appreciated that, during a heating cycle, the cooling dampers (58) are typically or mostly in the closed configuration and, during a cooling cycle, the heating dampers (56) are typically or mostly in the closed configuration, as can be easily understood by a person skilled in the art.

Thus, each treatment chamber (22) is independently controllable since a set of heating dampers (56) and a set of cooling dampers (58) are associated with each treatment chamber (22). Consequently, each chamber (22) can carry out its manufacturing cycle independently of the other chambers (22). In other words, the heating and cooling steps of each chamber (22) can be time-staggered. For instance and without being limitative, at a predetermined moment, a first chamber (22) can begin the heating cycle, while, simultaneously, a second chamber (22) is in the middle of the heating cycle, a third chamber (22) is at the end of the heating cycle, a fourth chamber (22) begins the cooling cycle, and so on. Thus, the product(s) to be treated can be prepared for and feed into one treatment chamber (22) while the other treatment chambers are in a heat treatment process. Similarly, the treated product(s) can be removed from one treatment chambers (22) while the other chambers (22) are carrying out a heat treatment process.

The gas flow rate and the temperature within each treatment chamber (22) are preferably controlled with the damper openings, although other suitable ways may be used with the present furnace, as can be easily understood by a person skilled in the art.

As also mentioned above, and when referring to FIG. 6, each treatment chamber (22) has its own product door (30) to introduce into and remove from the treatment chamber (22) one or several products to be heat treated. The product door (30) is thus defined in one of the walls (ex. lateral wall (28)) of the inner housing (32). Similarly, the outer housing (34) also includes doors (60) to provide access to the product door (30). In the embodiment shown, each product door (30) is associated with a respective one of the outer housing doors (60) and is substantially in register therewith. Thus, each treatment chamber (22) preferably has one product door (30) and one outer housing door (60). Doors (30,60) are mounted to the lateral walls of the inner and outer housings (32,34) and are configurable in an open configuration to allow access to the treatment chambers (22) through the cooling chamber (38) and in a closed configuration to prevent access to the treatment chambers (22) and the cooling chamber (38). Appropriate seals can be provided either on the inner and outer housing lateral walls and/or on the doors (30,60) to reduce gas exchange through the openings in the closed configuration of the doors (30,60).

One skilled in the art will also appreciate that the shape of the openings and the associated door (30,60) can vary and that the doors (30,60) can be mounted by several appropriate manners to the housings (32,34). Several mechanisms can also be used to operate the doors (30,60) between open and closed configurations, or even intermediate adjustable configurations, whether manually or remotely actuated by a user of the present heat treatment furnace.

According to a preferred embodiment of the present invention, trays (70) carrying the product(s) to be heat treated are inserted in the heat treatment chamber (22) through the outer housing doors (60) and the product doors (30). FIGS. 3 and 4 show trays (70) fully inserted in one of the treatment chambers (22). Even in the fully inserted configuration, sections (72,74) of the trays (70) preferably extend in the cooling chamber (38) and outwardly of the heat treatment furnace (20), as it will be described in greater detail hereinbelow.

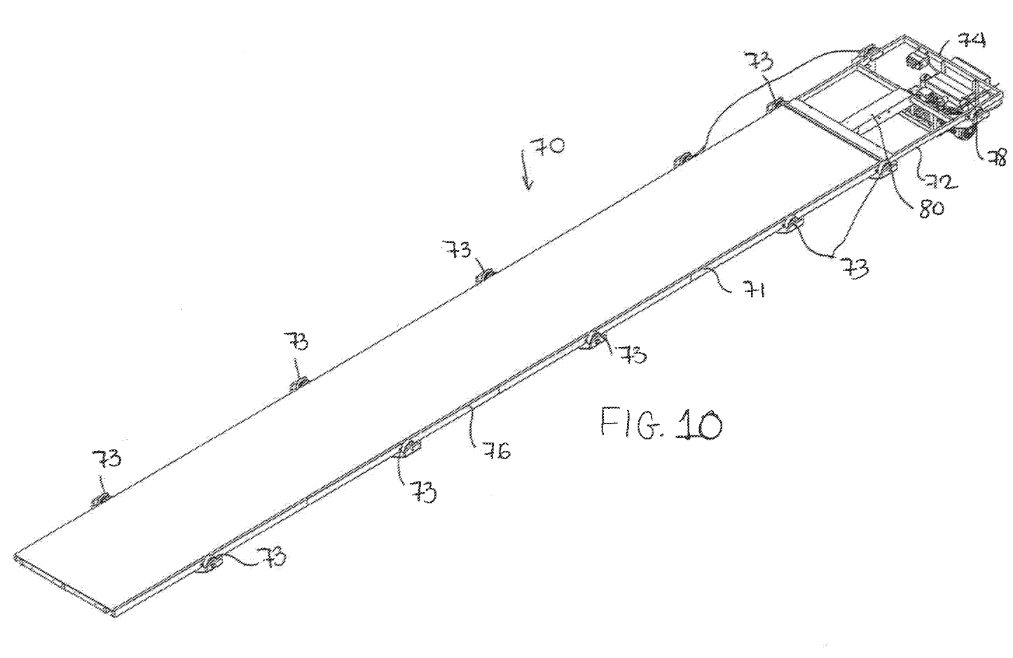

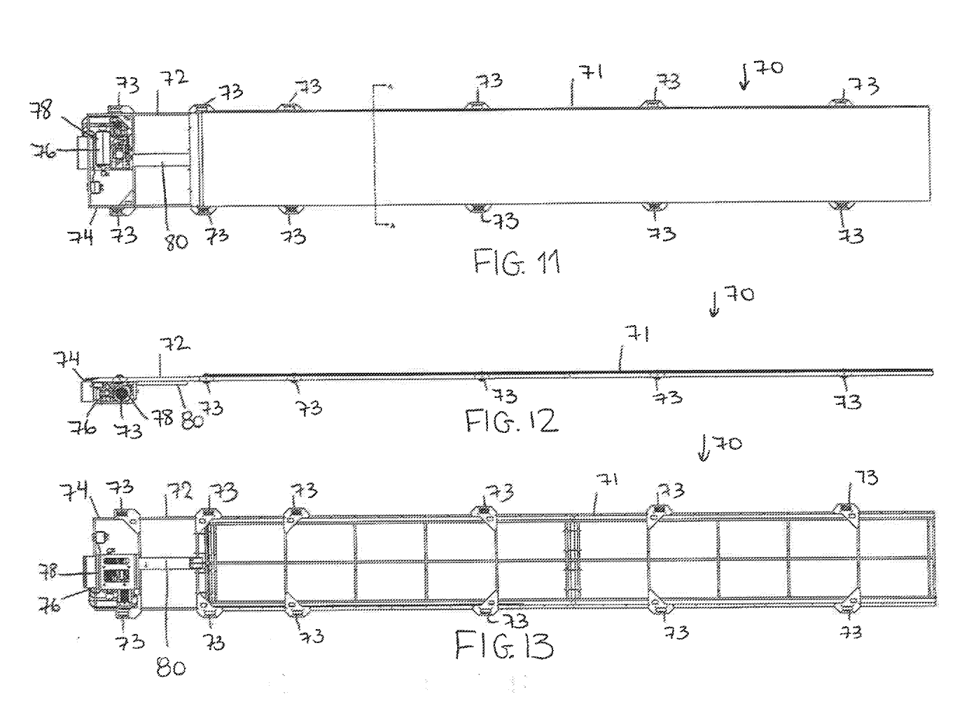

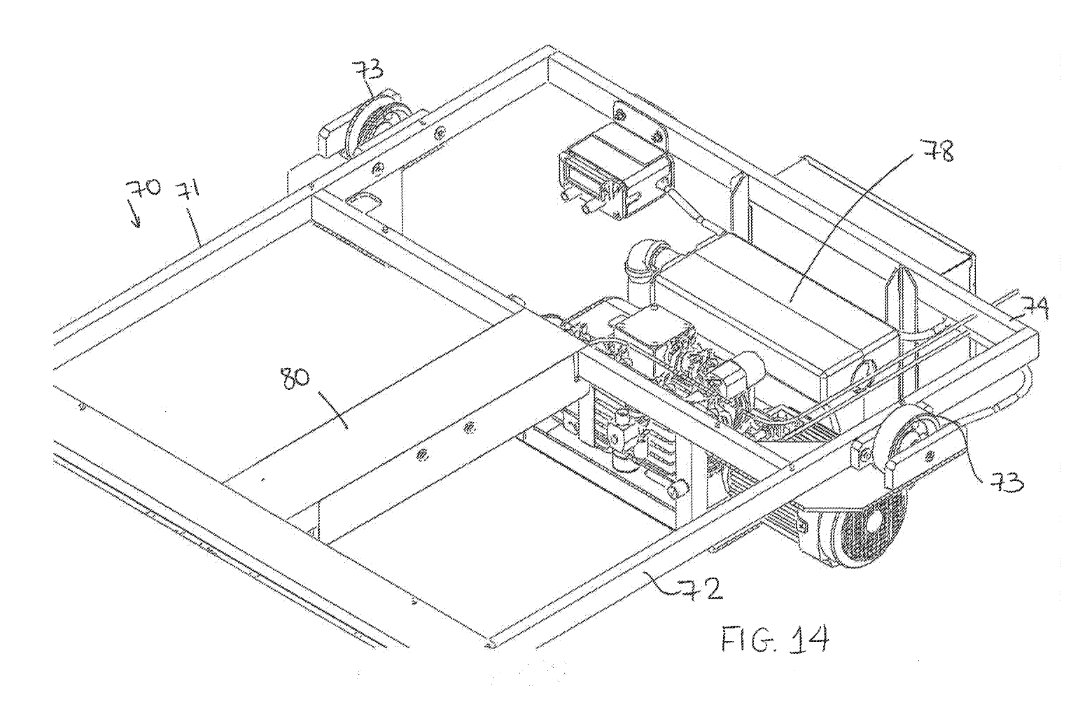

Namely, referring to FIGS. 10 to 14, there is shown an embodiment of the tray (70) for the heat treatment furnace (20). The tray (70) includes a frame (71) preferably supported by rollers (73) to facilitate its displacement between the assembling unit and the furnace (20), and within the furnace (20). The tray frame (71) includes a furnace section (76), a vacuum unit section (74), and an extension section (72) extending between the vacuum unit section (74) and the furnace section (76). The furnace section (76) is designed to be inserted in one of the furnace chambers (22) when the tray (70) is fully inserted in the furnace (20). The vacuum unit section (74) is located outwardly of the outer housing (34) when the tray (70) is fully inserted in the furnace (20). For the above-described embodiment of the furnace (20), the extension section (72) is preferably located in the cooling chamber (38) of the furnace (38), on the same side of the product doors (30), when the tray (30) is fully inserted in the furnace (20).

Preferably also, the furnace section (46) is designed to carry and support one or several products to be heat treated in the furnace (20) while the vacuum unit section (74) is designed to support a vacuum unit (78) including a pump. Gas conduits housed in a gas conduit and wire housing (80) operatively connected to the pump of the vacuum unit (78) extend between the furnace section (76) and the vacuum unit section (74) and are inserted in one of the treatment chambers (22) during heat treatment in such manner that vacuum can be maintained in associated with the product(s) to be heat treated. Appropriate sensors or detectors can also be mounted to the furnace section (76) of the tray (70) and wires (not shown) housed in the gas conduit and wire housing (80) can extend between the furnace section (76) and the vacuum unit section (74) to transmit data to the vacuum unit (78) or to a controller, which can also be mounted to the vacuum unit section (74) of the tray (70).

It is appreciated that the design of the tray (70) can vary in accordance with the heat treatment furnace, the treatment chamber design, and the product(s) to be heat treated. Indeed, a person skilled in the art will appreciate that several embodiments of vacuum units (78) and/or other types of units (used for monitoring, processing, etc. the content of a corresponding treatment chamber (22)) can be used in combination with the tray (70).

In a particular application, the heat treatment furnace (20) is designed to permanently bond laminated solar panels, i.e. the solar panels are cured in the furnace (20). In this application, each treatment chamber (22) is designed to receive one tray (70) having the laminated solar panel disposed therein. The vacuum unit section (74) of the tray (70) includes the vacuum unit (78) and its pump designed and configured to create a vacuum between the tray (70) having the laminated solar panels disposed therein and a diaphragm extending above the laminated solar panels. The vacuum is created before inserting the tray (70) in the furnace (20) and is maintained continuously during the insertion of the tray (70) within the furnace (20) and during the heating cycle. The vacuum applies a uniformly distributed pressure on the solar panels during the curing process. In the embodiment shown and as mentioned above, the vacuum units (78) and their pumps are located outwardly of the heat treatment furnace (20) when the trays (70) are fully inserted in the treatment chambers (22). The vacuum section (74) of the tray (70) is located on one side of the superposed chambers (22) opposed to the cooling blower (54).

To maintain the vacuum during the transfer of the tray (70) from the assembling unit to the heat treatment chamber (22), and according to a preferred embodiment of the present invention, power is continuously provided to the vacuum unit (78). In a non-limitative embodiment, power is preferably provided by an outer supply during solar panel assembling. Preferably also, power is then simultaneously provided by the outer supply and by the furnace (20) while inserting the tray (70) in the treatment chamber (22). Finally, power is disconnected from the outer supply during the heat treatment process.

It is appreciated that the configuration and the number of components including the treatment chambers (22), the heating and cooling dampers (56,58), the cooling chamber (38), the combustion chamber (36), the blowers (50,52), and the heat generating unit (48) can vary from the embodiment(s) described above. Furthermore, it is appreciated that each treatment chamber (22) can include its own heating and/or cooling unit(s) instead of having a common heating and/or cooling unit(s) for all chambers.

For instance, the treatment chambers can be configured in a horizontally adjacent configuration or a vertically-adjacent configuration or a combination thereof of any other suitable configuration. The outer housing (34) can fully or partially enclose the inner housing (32). The shape and location of the combustion and cooling chambers (36,38) can vary. The number and location of heat generating unit(s) and the cooling and heating blower(s) can also vary.

Finally, and according to the present invention, the heat treatment furnace (20) and corresponding components are preferably made of substantially rigid materials, such as metallic materials (stainless steel, etc.), hardened polymers, composite materials, and/or any other adequate material, while other components of the system according to the present invention, with the object of obtaining the resulting advantages briefly discussed hereinabove, may be made of any other appropriate material, depending on the particular applications and the environment for which the system is designed, and the different parameters in play, as can be easily understood by a person skilled in the art.

As now be better appreciated, in view of the present description, and the accompanying drawings, the present invention is an improvement over prior art in that the multi-chamber heat treatment furnace (20) described above increases the productivity and reduces the downtime between two lots in a batch process, when compared to conventional systems known in the art. Furthermore, energy consumption for heat treatment is reduced as the entire furnace (20) can be operated in a manner so as to never be entirely cooled down for the cooling cycle or for preparation of the next load. The continuous output of the multi-chamber heat treatment furnace (20) is more efficient in that less in-process material and or inventory is required. Additionally, an improved level of quality control is achieved as defective parts can be identified and serviced sooner.

Although preferred embodiments of the present invention have been briefly described herein and illustrated in the accompanying drawings, it is to be understood that the invention is not limited to these embodiments and that various changes and modifications could be made without departing form the scope and spirit of the present invention, as defined in the appended claims.

1. A heat treatment furnace for simultaneously heat processing a plurality of products at different respective heat treatment states, the heat treatment furnace comprising:
a plurality of treatment chambers each configurable for heat processing a given product, and each being provided with a corresponding product door selectively operable between open and closed configurations for respectively allowing the introduction and removal of the given product to be processed inside the treatment chamber;
at least one first damper and at least one second damper associated with each corresponding treatment chamber, each damper being selectively operable between at least one open configuration where at least one processing fluid of the furnace is allowed to enter the corresponding treatment chamber and at least one closed configuration where said at least one processing fluid is prevented from entering the corresponding treatment chamber;
a first source of processing fluid being fluidly connected to each treatment chamber via a corresponding damper thereof for providing said treatment chamber with a first processing fluid; and
a second source of processing fluid being fluidly connected to each treatment chamber via a corresponding damper thereof for providing said treatment chamber with a second processing fluid;
the dampers of each treatment chamber being selectively and independently adjustable with respect to one another so as to allow simultaneous heat processing of a plurality of products in different treatment chambers at different respective heat treatment states depending on the amount of first and second processing fluids allowed to enter in each treatment chamber via the dampers thereof.

2. A heat treatment furnace according to claim 1, wherein the treatment chambers are superimposed with respect to one another.

3. A heat treatment furnace according to claim 1, wherein each pair of neighbouring treatment chambers are separated by at least one insulated partition wall and each partition wall provides a chamber floor for a first treatment chamber and a chamber ceiling for a second treatment chamber.

4. (canceled)

5. (canceled)

6. (canceled)

7. (canceled)

8. A heat treatment furnace according to claim 1, wherein said at least one first damper comprises a pair of dampers each being mounted onto a corresponding longitudinal wall, and wherein said at least one second damper also comprises a pair of dampers each being mounted onto a corresponding lateral wall and each first damper is a heating damper and wherein each second damper is a cooling damper.

9. A treatment furnace according to claim 1, wherein each damper is adjustably movable with respect to a corresponding opening of a given treatment chamber via a controller so as to selectively and adjustable vary the effective passage of said corresponding opening.

10. (canceled)

11. A heat treatment furnace according to claim 1, wherein the first processing fluid is a heating fluid, and wherein the second processing fluid is a cooling fluid and each processing fluid is re-circulated within a corresponding fluid circuit of the heat treatment furnace.

12. (canceled)

13. A heat treatment furnace according to claim 1, wherein the heat treatment furnace comprises a heat generating assembly for generating hot air, said heat generating assembly being fluidly connected to the treatment chambers via heating dampers, and wherein the heat treatment furnace further comprises a cooling assembly for providing cold air, said heat cooling assembly being fluidly connected to the treatment chambers via cooling dampers, the heat generating assembly comprises at least one heating blower for blowing hot air to the heating dampers of the treatment chambers via a corresponding outer housing, and wherein the cooling assembly comprises at least one cooling blower for blowing cold air to the cooling dampers of the treatment chambers via a corresponding inner housing enclosed in the outer housing and containing the treatment chambers.

14. (canceled)

15. (canceled)

16. (canceled)

17. A heat treatment furnace according to claim 13, wherein the outer housing comprises a combustion chamber and a cooling chamber, the combustion chamber comprising a main section located below the inner housing of the heat treatment furnace, and a pair of longitudinal sections extending upwardly from the main section, each longitudinal section being located on a respective side of the inner housing, the cooling chamber comprising a pair of lateral sections extending upwardly from a bottom section, each lateral section being located on a respective side of the inner housing, and being fluidly connected to a central duct extending above an uppermost treatment chamber of the heat treatment furnace, the combustion chamber and the cooling chamber being each fluidly connected to the treatment chambers, and at least one of the combustion and cooling chambers comprises a heat exchanger.

18. (canceled)

19. (canceled)

20. (canceled)

21. (canceled)

22. (canceled)

23. A heat treatment furnace according to claim 8, wherein the cooling dampers are closed during a heating cycle of the heat treatment furnace, and wherein the heating dampers are closed during a cooling cycle of the heat treatment furnace.

24. A heat treatment furnace according to claim 1, wherein heating and cooling cycles within the treatment chambers of the heat treatment are time-staggered.

25. A heat treatment furnace according to claim 1, wherein each treatment chamber includes a product door and a housing door, the product door and housing door are respectively mounted onto a lateral wall of the treatment chamber and onto an outer housing of the heat treatment furnace with the product door and the housing door of each treatment chamber being in register.

26. (canceled)

27. (canceled)

28. (canceled)

29. A heat treatment furnace according to claim 1, wherein the heat treatment furnace further comprises at least one tray having a treatment portion removably insertable into a corresponding treatment chamber for supporting the product to be thermally processed inside said corresponding treatment chamber.

30. A heat treatment furnace according to claim 29, wherein each tray further comprises an outer portion extendable outwardly from the corresponding treatment chamber and the outer portion of the tray is extendable inside a cooling chamber of the heat treatment furnace.

31. (canceled)

32. (canceled)

33. A heat treatment furnace according to claim 29, wherein each tray comprises:
a furnace section removably insertable into a corresponding treatment chamber for supporting the product to be thermally processed inside a corresponding treatment chamber;
a vacuum unit section configured for extending outwardly out from an outer housing of the heat treatment furnace when the tray is inserted into the corresponding treatment chamber; and
an extension section extending between the furnace section and the vacuum unit section, and configured for lying in a cooling chamber of the heat treatment furnace when the tray is inserted into the corresponding treatment chamber.

34. A heat treatment furnace according to claim 33, wherein the vacuum unit section is provided with a corresponding vacuum assembly operatively connectable to the furnace section for selectively maintaining a vacuum condition inside a corresponding treatment chamber when the furnace section of the tray is lodged into said corresponding treatment chamber.

35. A heat treatment furnace according to claim 33, wherein at least one sensor is provided on the furnace section of the tray for relaying data from the treatment chamber to a controller of the vacuum assembly.

36. A heat treatment furnace according to claim 1, wherein a vacuum condition is created inside a corresponding treatment chamber of the heat treatment chamber before inserting a corresponding tray with a product to be processed inside said corresponding treatment chamber and the vacuum condition inside the treatment chamber is further assisted by the vacuum assembly of the tray.

37. (canceled)

38. A heat treatment furnace according to claim 1, wherein the heat treatment furnace is used for processing solar panels, and wherein the heat processing includes a curing processing of some components of the solar panels.

39. A multi-chamber furnace comprising:
a plurality of treatment chambers isolated from one another and each having at least two heating dampers and at least two cooling dampers, the heating and cooling dampers being configurable in a closed configuration and a plurality of open configurations and being controllable to adjust a gas flowrate in the respective treatment chamber, and at least one product door allowing product introduction in and product removal from the respective treatment chamber;
at least one heat generating unit and at least one heating blower in gas communication with the heating dampers of the chambers with gas communication being allowed with the chambers in the open configurations of the heating dampers and gas communication being prevented in the closed configuration of the heating dampers; and
at least one cooling blower in gas communication with the cooling dampers of the chambers with gas communication being allowed with the chambers in the open configurations of the cooling dampers and gas communication being prevented in the closed configuration of the cooling dampers.

40. A multi-chamber furnace according to claim 39, wherein the at least two heating dampers are located on two opposite walls of the treatment chamber, the at least two cooling dampers are located on opposite walls of the treatment chamber, and the heating dampers and the cooling dampers are independently controllable from one another.

41. (canceled)

42. (canceled)

43. A multi-chamber furnace according to claim 39, wherein the at least one heat generating unit and the at least one heating blower are located in or communicate with a combustion chamber at least partially enclosing the treatment chambers, and the at least one cooling blower is located in or communicate with a cooling chamber at least partially enclosing the treatment chambers.

44. (canceled)

45. A tray for a heat treatment furnace comprising:
a furnace section having a base for supporting at least one product to be heat treated and insertable in the heat treatment furnace; and
a vacuum unit section having a vacuum unit mounted thereto, remaining outside the heat treatment furnace when the furnace section is inserted therein, and having a gas conduit operatively connected to the vacuum unit and extending to the furnace section for maintaining vacuum in association with the at least one product supported by the furnace section.
